(19) United States
(12) Patent Application Publication
(10) Pub. No.: US 2005/0188921 A1
(43) Pub. Date: Sep. 1, 2005

(54) Matrix assisted pulsed-laser evaporation technique for coating a medical device and associated system and medical device

(76) Inventor: Anthony Malone, Miltown Malbay (IE)

Correspondence Address: KENYON & KENYON, 1500 K STREET NW, SUITE 700, WASHINGTON, DC, 20005, US

(21) Appl. No.: 10/789,606

(22) Filed: Feb. 27, 2004

(51) Int. Cl. C23C 16/00

(52) U.S. Cl. 118/715

(57) ABSTRACT

A method is provided for coating at least a portion of at least one medical device. The method includes arranging the at least one medical device in a vapor cone and directing a laser at a frozen target. The target includes an agent and the laser vaporizes the agent into the vapor cone. A device is provided for coating at least one medical device. The device includes a target assembly, a laser directed at the target assembly, and an arrangement adapted to hold the at least one medical device in a vapor cone. The vapor cone originates at a target point that a laser beam or a laser pulse contacts a frozen target in the target assembly. A medical device is provided having a coating applied by a method. The method includes arranging the medical device in a vapor cone and directing a laser at a frozen target. The frozen target includes an agent and the laser vaporizes the agent into the vapor cone.

### FIELD OF THE INVENTION

The present invention relates to the manufacturing of medical devices. More particularly, the present invention relates to a device and method for coating medical devices using a Matrix Assisted Pulsed-Laser Evaporation (MAPLE) technique.

### BACKGROUND INFORMATION

Medical devices may be coated so that the surfaces of such devices have desired properties or effects. For example, it may be useful to coat medical devices to provide for the localized delivery of therapeutic agents to target locations within the body, such as to treat localized disease (e.g., heart disease) or occluded body lumens. Localized drug delivery may avoid some of the problems of systemic drug administration, which may be accompanied by unwanted effects on parts of the body which are not to be treated. Additionally, treatment of the afflicted part of the body may require a high concentration of therapeutic agent that may not be achievable by systemic administration. Localized drug delivery may be achieved, for example, by coating balloon catheters, stents and the like with the therapeutic agent to be locally delivered. The coating on medical devices may provide for controlled release, which may include long-term or sustained release, of a bioactive material.

Aside from facilitating localized drug delivery, medical devices may be coated with materials to provide beneficial surface properties. For example, medical devices are often coated with radiopaque materials to allow for fluoroscopic visualization during placement in the body. It is also useful to coat certain devices to achieve enhanced biocompatibility and to improve surface properties such as lubriciousness.

Coatings have been applied to medical devices by processes such as dipping, spraying, vapor deposition, plasma polymerization, and electrodeposition. Although these processes have been used to produce satisfactory coatings, they have numerous, associated potential drawbacks. For example, it may be difficult to achieve coatings of uniform thicknesses, both on individual parts and on batches of parts. Further, many conventional processes require multiple coating steps or stages for the application of a second coating material, or to allow for drying between coating steps or after the final coating step.

There is, therefore, a need for a cost-effective method of coating medical devices that results in uniform, defect-free coatings and uniform drug doses per unit device. The method would allow for a multiple stage coating in order to apply a bioactive material that may be environmentally sensitive, e.g., due to heat and light (including ultra-violet) exposure. Multiple stage coating may also be used to prevent degradation of the bioactive material due to process-related forces (e.g., shear). The method would thus allow for better control of the sensitivity of the bioactive material and reduce any potential degradation due to environmental issues. The method would also reduce variations in the coating properties.

Current coating techniques may result in thicker coatings, resulting in excess bioactive ingredient being deposited on the medical device. Excessive bioactive ingredient delivered to the lumen may be toxic. Thinner coatings may allow more precise deposition of bioactive ingredient(s) on the medical device, and may allow greater precision in the delivery of the bioactive agent. Therefore, an efficient method of applying thin coats of materials to medical devices is desired.

The MAPLE technique has been used to provide thin coatings. “The deposition, structure, pattern deposition, and activity of biomaterial thin-films by matrix-assisted pulsed-laser evaporation (MAPLE) and MAPLE direct write,” in Thin Solid Films (volumes 398-399, November 2001, pages 607-614), discusses the MAPLE process and is incorporated herein by reference.

### SUMMARY

According to an exemplary method of the present invention, medical devices are coated using a Matrix Assisted Pulsed-Laser Evaporation (MAPLE) technique. A laser is directed at a target including a drug and polymer suspended in a solution which may be frozen. A frozen target may be arranged on a refrigerated rotating assembly. Alternatively, a liquid target may be arranged in a container at the target and may include a stirrer or sonicator. The laser may be directed at the target and vaporize the target into a vapor cone. A medical device may be placed in the vapor cone and may be situated close to the target. The vaporized target may include the drug/polymer combination and the vaporized solvent. The vaporized material may deposit in a controlled fashion on the target, and may deposit at a slow rate. The solvent may evaporate from the medical device and may be transported out of an evaporation chamber by a pump. A secondary gas source may assist in delivering the vaporized coating from the target to the medical device.

The process may produce an advantageous degree of specificity. For instance, small areas of a medical device (for instance, the ends of a medical device) may be coated to a separate product specification than the remainder of the medical device. The MAPLE process may provide greater freedom in the selection of active agents due to fewer degradation effects. The MAPLE process may provide an increased ability to control release-kinetics of the active agents due to the ability to control coating finish. The MAPLE process may allow greater freedom in the use of polymer substrates including those involving cross-linking and bonding of radicals.

A device for coating at least one medical device includes a target assembly adapted to hold a target and a laser directed at the target in the target assembly. The laser is adapted to emit a laser beam and/or a laser pulse. The device also includes an arrangement adapted to hold the at least one medical device in a vapor cone. The target includes a drug and a polymer evenly distributed throughout the frozen target matrix or the solution target matrix. The vapor cone originates at a target point that the laser beam and/or the laser pulse contacts the target.

A medical device has a coating applied by a method. The method includes directing a laser at a target and vaporizing by the laser at least a portion of the target into a vapor cone. The method also includes arranging the medical device in the vapor cone. The target includes a drug and a polymer.

### BRIEF DESCRIPTION OF THE DRAWINGS

FIG. 1 illustrates schematically an exemplary embodiment of a system using MAPLE to coat a medical device using a frozen target.

FIG. 2 illustrates schematically an alternative exemplary embodiment of a system using MAPLE to coat a medical device using a liquid target.

FIG. 3 is a flowchart illustrating an exemplary method according to the present invention.

### DETAILED DESCRIPTION

A drug polymer solution may be prepared by dissolving an appropriate amount of drug and polymer in a solvent. After mixing and filtration, the solution may be cryogenically frozen ensuring that the drug and polymer solute is evenly dispersed within the frozen suspension. A segment of the frozen block may be mounted onto a refrigerated rotating assembly. A laser pulse of specific wavelength may be directed at the frozen matrix. The matrix may preferentially absorb the laser pulse and allow the solute molecules to be gently desorbed from the block. At a molecular level, the incident laser energy may be absorbed by the bulk solvent molecules and converted into kinetic energy, which may then be transferred to the embedded solute through collective collisions, resulting in the desorption of the large molecular weight drug and polymer molecules.

The laser pulse may generate a forward directed vapor cone containing the evaporated material. When a substrate (for instance, a stent) is placed in the path of the vapor cone, it may be uniformly coated with a drug-polymer film while the volatile solvent molecules may be removed by the chamber's vacuum pump.

Optimization of control factors such as drug solution concentrations, freezing conditions, laser wavelength and distance from the frozen matrix to the stent substrate may allow for coating medical devices with a film of predetermined concentration and thickness.

This technique may allow for the control of the stent coating thickness on a molecular layer by layer scale. This control may not compromise the enhanced film adhesion to the medical device. Conventional methods of coating stents with a drug-polymer layer, such as spraying or dipping, may require a solution of the drug-polymer to physically wet the surface of the stent. Spraying or dipping may cause uneven and unpredictable wetting, and distribution and evaporation of the solvent molecules may result in a non-uniform coating. A non-uniform coating may lead to the unit failing Kinetic Drug Release, drug uniformity and coating thickness specifications.

The MAPLE technique may also be used to coat a medical device with more than one drug-polymer film. Once one coating has been deposited onto the stent another frozen block of drug-polymer matrix may be mounted in the laser path and used to deposit a new drug-polymer coat over the first. As the solvent has been evaporated before reaching the surface, there may be no medium for mixing between the two distinct layers, thus giving a layer discrete layer interface.

There may be excellent material efficiency using this method, since the drug-polymer solution may be deposited on the medical device on a molecular scale. As there is a discreet amount, and not an excess, of material in the vaporized cone emanating from the frozen matrix, large losses of unused material removed in the exhaust stream from the evaporation chamber may be avoided.

Alternatively, instead of freezing the target drug-polymer matrix, it may be left as a solution with the stent positioned vertically over the solution and the laser positioned at an angle to the side. The drug-polymer distribution within the solution may be kept uniform by keeping the solution mixed by using a stirrer, a sonicator, or by any other appropriate means or method.

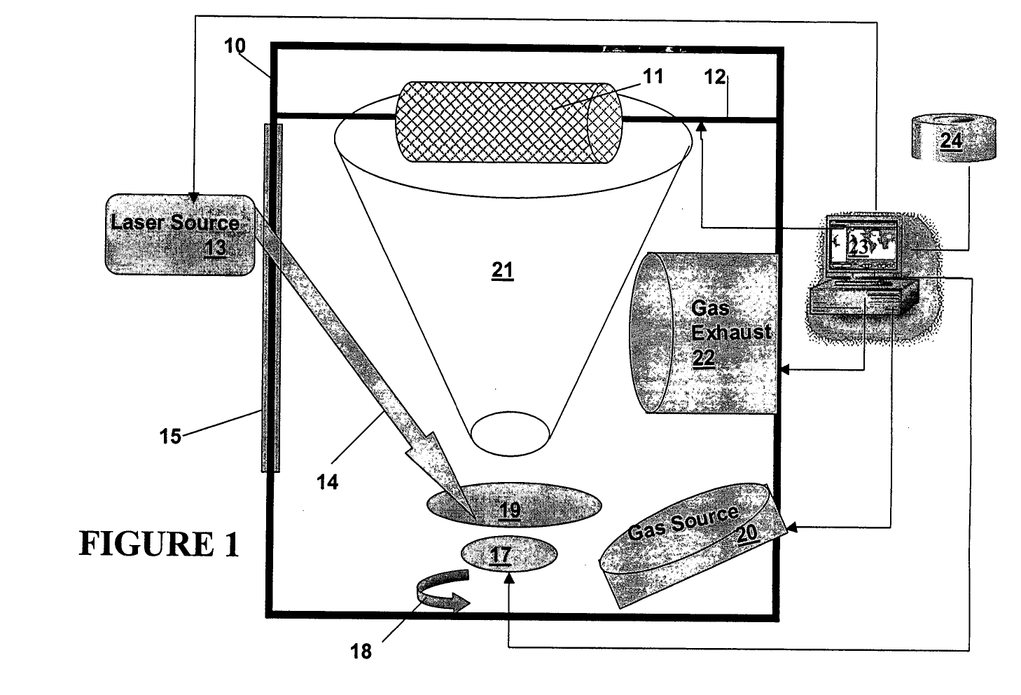

FIG. 1 includes evaporation chamber 10 enclosing medical device 11 arranged on holder 12. Holder 12 may be adapted to move medical device 11 laterally, longitudinally, vertically, and/or rotatably. Holder 12 may be adapted to hold more than one medical device, and may be adapted to move medical device 11 out of evaporation chamber 10 and move another medical device 11 into evaporation chamber 10. Holder 12 may be adapted to continuously move medical device 11 and replace it with a new medical device 11 in order to coat medical device 11 in a continuous fashion rather than in a batch coating process.

Laser source 13 is situated outside evaporation chamber 10 in such a manner that it projects laser beam 14 through window 15 of evaporation chamber 10. Alternatively, laser source 13 may be situated inside evaporation chamber 10, and evaporation chamber 10 may or may not have window 15. Laser source 13 may be any type of laser that may be capable of emitting a laser beam and/or a laser pulse of any appropriate frequency and/or at various wavelengths. Laser beam 14 may possibly be a beam of ultraviolet (UV) light. Laser beam 14 may impinge on target 19, which may be a frozen solution of a drug and polymer. The drug and polymer combination in the frozen solution of target 19 may be a therapeutic and/or bioactive agent useful for any number of purposes. Some of the possibilities for therapeutics and/or bioactive agents coated on a medical device are discussed below. When laser beam 14 impinges on target 19, the laser may impart energy to the molecules in the frozen solution matrix (that is, target 19), and may vaporize the solute, drug, and/or polymer. The evaporated material may eject from the surface of target 19 and may form vapor cone 21. Vapor cone 21 may include molecules of drug and/or polymer (solute) moving with some velocity from target 19 towards medical device 11. The velocity of the molecules in vapor cone 21 may be provided solely by the vaporization of the frozen material of target 19 in a vacuum provided by evaporation chamber 10.

Additionally, there may be a pressure differential assisting the movement of molecules in vapor cone 21 which may be created by positioning a pump near the top of vacuum chamber 10 (for instance, gas exhaust 22). Alternatively, gas source 20 may be utilized to assist the movement, and/or increase the velocity, of molecules of solute, drug, and/or polymer moving from target 19 towards medical device 11. Gas source 20 may provide a flow of an inert gas and/or a material that will not interfere with the drug, bioactive agent, and/or polymer being deposited on medical device 11. By positioning the vacuum pump or gas exhaust 22 (for instance, an extract fan) on top of the chamber 10 may remove the necessity of the extra gas source.

Target 19 may be situated on rotating refrigerated assembly 17. Rotating refrigerated assembly 17 may be refrigerated and thereby maintain target 19 in a frozen state. Additionally, rotating refrigerated assembly 17 may rotate to expose new areas of target 19 to laser beam 14, thereby enabling all of target 19 to be vaporized and utilized for coating medical device 11. Alternatively, all of evaporation chamber 10 may be refrigerated to maintain target 19 in a frozen state. Additionally and alternatively, laser source 13 may redirect laser beam 14 to cause laser beam 14 to impinge on new areas of target 19. Additionally and alternatively, window 15 may operate to focus and redirect laser beam 14.

The molecules of solute, drug, and/or polymer moving from target 19 towards medical device 11 may deposit on medical device 11 molecule-by-molecule. The deposition of molecules may therefore be very controlled and may enable very thin layers to be deposited. The solute in the vapor may deposit on medical device 11, but may subsequently evaporate again into evaporation chamber 10. Evaporated solute may be removed from evaporation chamber 10 by gas exhaust 22 (which may be an air pump or extract fan). Gas exhaust 22 may enable evaporation chamber 10 to operate continuously in a vacuum or near-vacuum state, thereby promoting the evaporation of any deposited liquid solute from medical device 11 or elsewhere in evaporation chamber 10.

Processor 23 may control any or all of holder 12, laser source 13, rotating refrigerated assembly 17, gas source 20, and gas exhaust 22. Processor 23 may be electrically coupled to memory 24, which may include process parameters for coating various types of medical devices with various types of drugs and bioactive agents.

Alternative exemplary embodiments may provide for additional lasers and/or additional targets for the deposition of multiple layers. Additionally, it may be possible to coat just a portion of medical device 11, for instance, the ends of medical device 11, by appropriate positioning or moving of medical device 11 in vapor cone 21. Additionally and alternatively, masks and/or other barriers may be utilized to promote the coating of a portion of medical device 11, while maintaining another portion of medical device 11 free of coating.

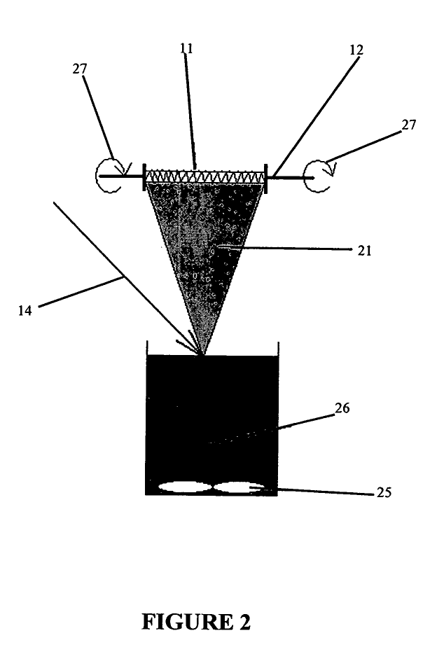

FIG. 2 illustrates an alternative exemplary embodiment of a system using the MAPLE technique to coat medical device 11 using liquid target 26. Instead of freezing the target drug-polymer matrix, it may be left as a solution with medical device 11 positioned vertically over liquid target 26 and the laser positioned at an angle to the side. In this manner, laser beam 14 (or alternatively, a laser pulse) impinges on the surface of liquid target 26, causing liquid target 26 to vaporize. Vapor cone 21 is formed above the surface of liquid target 26. The drug-polymer distribution within liquid target 26 is maintained uniformly mixed by mixing the solution using stirrer 25. Stirrer 25 may operate by mechanically moving within liquid target 26 at a rate sufficient to cause the mixing of the constituents (i.e., the drug, polymer, and/or solution) of liquid target 26. Additionally or alternatively, an alternative arrangement or method for mixing liquid target 26 may be provided. In particular, a sonicator may be used to agitate liquid target 26 and maintain the solution in a uniformly mixed state.

A sonicator works by an ultrasonic generator producing an electrical signal at a particular frequency. A converter/transducer transforms the electrical signal into mechanical vibration. The mechanical vibration is transmitted down the length of a horn/probe. The tip of the horn/probe expands and contracts at the same frequency as the electrical signal through a prescribed amplitude (i.e., distance). When placed in liquid target 26, the rapid (i.e., 20 kHz) vibration of the horn/probe tip causes cavitation, i.e., the formation and violent collapse of microscopic bubbles. The collapse of the thousands of cavitation bubbles releases energy in the cavitation field. Objects and surfaces that are within the cavitation field may be vigourously mixed by the released energy.

Additionally shown in FIG. 2 is holder 12 holding medical device 11 and adapted to rotate in the direction of arrows 27. Additionally, holder 12 may be adapted to rotate in the opposite direction, or to move laterally, horizontally, and/or vertically.

The exemplary embodiment of FIG. 2 may have some or all of the following criteria. The assembly described in FIG. 2 may be contained within an isolated unit that is purged with nitrogen gas ensuring that no oxygen is present, thereby reducing the risk of combustion of the solution (in particular the solvent) by the laser beam. Additionally, the risk of combustion/explosion of the solution may be minimized by selection of the appropriate UV laser wavelength. The solvents/solute in the drug solution may also be selected to minimize the explosion/combustion risk, as well as to achieve the required vapor plume. The angle of the laser pulse may be selected to promote creation of the required vapor plume. A vacuum or near-vacuum may be employed at the medical device side of the unit (i.e., evaporation chamber) so that the vapor plume is drawn towards the stent (e.g., the top of the figure near medical device 11 in FIG. 2). The excess solvent may be removed (either after vaporization from liquid target 26, or after depositing on, and subsequently evaporating from, medical device 11) by the system used to create the vacuum and/or pressure differential.

To ensure solute homogeneity it may be important that vigourous agitation is achieved. One major advantage of having a solution matrix over a frozen block matrix may be that there may be no need to cryogenically freeze the block, and uniform dispersal of the solute may be achieved as a result of constant mixing.

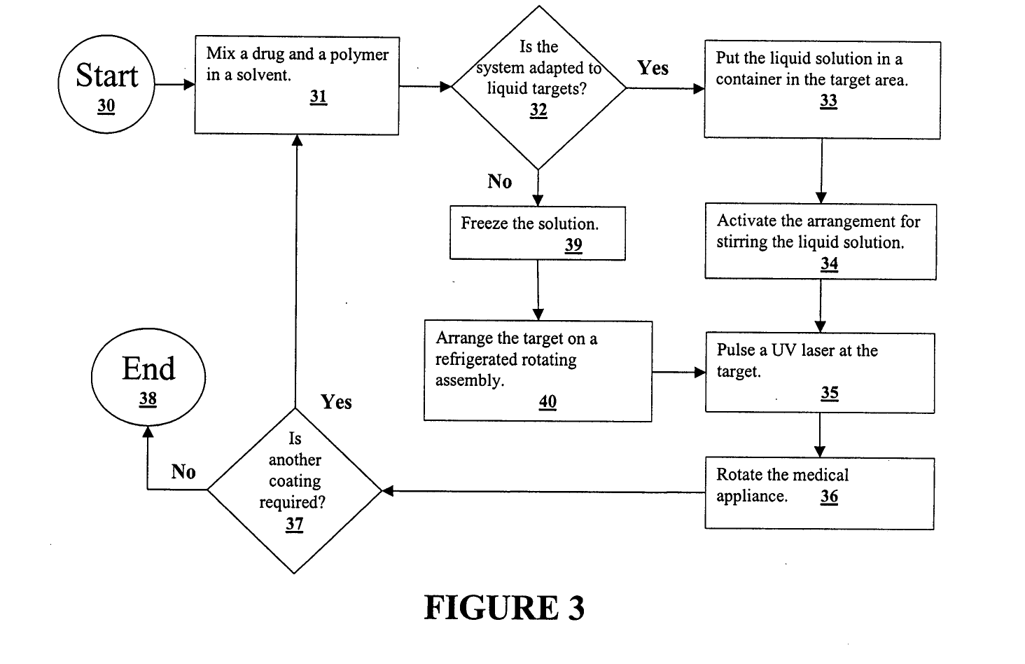

FIG. 3 is a flowchart illustrating an exemplary method according to the present invention. The flow in FIG. 3 begins in start circle 30 and proceeds to action 31 which indicates to mix a drug and a polymer in a solvent. From action 31 the flow proceeds to question 32, which ask whether the system is adapted to liquid targets. If the response to question 32 is in the affirmative, the flow proceeds to action 33, which indicates to put the liquid solution in a container in the target area. From action 33, the flow proceeds to action 34, which indicates to activate the arrangement for stirring the liquid solution. As indicated above, the arrangement for stirring the liquid solution may be a stirrer, a sonicator, and/or any other appropriate configuration adapted to stir the solution. From action 34, the flow proceeds to action 35, which indicates to pulse a UV laser (any other appropriate laser may be substituted for the UV laser) at the target. From action 35, the flow proceeds to action 36, which indicates to rotate the medical device. From action 36, the flow proceeds to question 37, which asks whether another coating is required. If the response to question 37 is in the negative, the flow proceeds to end circle 38. If the response to question 32 is in the negative, the flow proceeds to action 39, which indicates to freeze the solution. From action 39, the flow proceeds to action 40, which indicates to arrange the target on a refrigerated rotating assembly. From action 40, the flow proceeds to action 35. If the response to question 37 is in the affirmative, the flow proceeds to action 31.

Medical implants are used for innumerable medical purposes, including the reinforcement of recently re-enlarged lumens, the replacement of ruptured vessels, and the treatment of disease such as vascular disease by local pharmacotherapy, i.e., delivering therapeutic drug doses to target tissues while minimizing systemic side effects. Such localized delivery of therapeutic agents has been proposed or achieved using medical implants which both support a lumen within a patient's body and place appropriate coatings containing absorbable therapeutic agents at the implant location. Examples of such medical devices include catheters, guide wires, balloons, filters (e.g., vena cava filters), stents, stent grafts, vascular grafts, intraluminal paving systems, implants and other devices used in connection with drug-loaded polymer coatings. Such medical devices are implanted or otherwise utilized in body lumina and organs such as the coronary vasculature, esophagus, trachea, colon, biliary tract, urinary tract, prostate, brain, and the like.

The term “therapeutic agent” as used herein includes one or more “therapeutic agents” or “drugs”. The terms “therapeutic agents” and “drugs” are used interchangeably herein and include pharmaceutically active compounds, nucleic acids with and without carrier vectors such as lipids, compacting agents (such as histones), viruses (such as adenovirus, andenoassociated virus, retrovirus, lentivirus and α-virus), polymers, hyaluronic acid, proteins, cells and the like, with or without targeting sequences.

Specific examples of therapeutic agents used in conjunction with the present invention include, for example, pharmaceutically active compounds, proteins, cells, oligonucleotides, ribozymes, anti-sense oligonucleotides, DNA compacting agents, gene/vector systems (i.e., any vehicle that allows for the uptake and expression of nucleic acids), nucleic acids (including, for example, recombinant nucleic acids; naked DNA, cDNA, RNA; genomic DNA, cDNA or RNA in a non-infectious vector or in a viral vector and which further may have attached peptide targeting sequences; antisense nucleic acid (RNA or DNA); and DNA chimeras which include gene sequences and encoding for ferry proteins such as membrane translocating sequences (“MTS”) and herpes simplex virus-1 (“VP22”)), and viral, liposomes and cationic and anionic polymers and neutral polymers that are selected from a number of types depending on the desired application. Non-limiting examples of virus vectors or vectors derived from viral sources include adenoviral vectors, herpes simplex vectors, papilloma vectors, adeno-associated vectors, retroviral vectors, and the like. Non-limiting examples of biologically active solutes include anti-thrombogenic agents such as heparin, heparin derivatives, urokinase, and PPACK (dextrophenylalanine proline arginine chloromethylketone); antioxidants such as probucol and retinoic acid; angiogenic and anti-angiogenic agents and factors; anti-proliferative agents such as enoxaprin, angiopeptin, rapamycin, angiopeptin, monoclonal antibodies capable of blocking smooth muscle cell proliferation, hirudin, and acetylsalicylic acid; anti-inflammatory agents such as dexamethasone, prednisolone, corticosterone, budesonide, estrogen, sulfasalazine, acetyl salicylic acid, and mesalamine; calcium entry blockers such as verapamil, diltiazem and nifedipine; antineoplastic/antiproliferative/anti-mitotic agents such as paclitaxel, 5-fluorouracil, methotrexate, doxorubicin, daunorubicin, cyclosporine, cisplatin, vinblastine, vincristine, epothilones, endostatin, angiostatin and thymidine kinase inhibitors; antimicrobials such as triclosan, cephalosporins, aminoglycosides, and nitrofurantoin; anesthetic agents such as lidocaine, bupivacaine, and ropivacaine; nitric oxide (NO) donors such as linsidomine, molsidomine, L-arginine, NO-protein adducts, NO-carbohydrate adducts, polymeric or oligomeric NO adducts; anti-coagulants such as D-Phe-Pro-Arg chloromethyl ketone, an RGD peptide-containing compound, heparin, antithrombin compounds, platelet receptor antagonists, anti-thrombin antibodies, anti-platelet receptor antibodies, enoxaparin, hirudin, Warfarin sodium, Dicumarol, aspirin, prostaglandin inhibitors, platelet inhibitors and tick antiplatelet factors; vascular cell growth promotors such as growth factors, growth factor receptor antagonists, transcriptional activators, and translational promotors; vascular cell growth inhibitors such as growth factor inhibitors, growth factor receptor antagonists, transcriptional repressors, translational repressors, replication inhibitors, inhibitory antibodies, antibodies directed against growth factors, bifunctional molecules consisting of a growth factor and a cytotoxin, bifunctional molecules consisting of an antibody and a cytotoxin; cholesterol-lowering agents; vasodilating agents; agents which interfere with endogenous vascoactive mechanisms; survival genes which protect against cell death, such as anti-apoptotic Bcl-2 family factors and Akt kinase; and combinations thereof. Cells can be of human origin (autologous or allogenic) or from an animal source (xenogeneic), genetically engineered if desired to deliver proteins of interest at the insertion site. Any modifications are routinely made by one skilled in the art.

Polynucleotide sequences useful in practice of the invention include DNA or RNA sequences having a therapeutic effect after being taken up by a cell. Examples of therapeutic polynucleotides include anti-sense DNA and RNA; DNA coding for an anti-sense RNA; or DNA coding for tRNA or rRNA to replace defective or deficient endogenous molecules. The polynucleotides can also code for therapeutic proteins or polypeptides. A polypeptide is understood to be any translation product of a polynucleotide regardless of size, and whether glycosylated or not. Therapeutic proteins and polypeptides include as a primary example, those proteins or polypeptides that can compensate for defective or deficient species in an animal, or those that act through toxic effects to limit or remove harmful cells from the body. In addition, the polypeptides or proteins that can be injected, or whose DNA can be incorporated, include without limitation, angiogenic factors and other molecules competent to induce angiogenesis, including acidic and basic fibroblast growth factors, vascular endothelial growth factor, hif-1, epidermal growth factor, transforming growth factor α and β, platelet-derived endothelial growth factor, platelet-derived growth factor, tumor necrosis factor α, hepatocyte growth factor and insulin like growth factor; growth factors; cell cycle inhibitors including CDK inhibitors; anti-restenosis agents, including p15, p16, p18, p19, p21, p27, p53, p57, Rb, nFkB and E2F decoys, thymidine kinase (“TK”) and combinations thereof and other agents useful for interfering with cell proliferation, including agents for treating malignancies; and combinations thereof. Still other useful factors, which can be provided as polypeptides or as DNA encoding these polypeptides, include monocyte chemoattractant protein (“MCP-1”), and the family of bone morphogenic proteins (“BMP's”). The known proteins include BMP-2, BMP-3, BMP-4, BMP-5, BMP-6 (Vgr-1), BMP-7 (OP-1), BMP-8, BMP-9, BMP-10, BMP-11, BMP-12, BMP-13, BMP-14, BMP-15, and BMP-16. Currently preferred BMP's are any of BMP-2, BMP-3, BMP-4, BMP-5, BMP-6 and BMP-7. These dimeric proteins can be provided as homodimers, heterodimers, or combinations thereof, alone or together with other molecules. Alternatively or, in addition, molecules capable of inducing an upstream or downstream effect of a BMP can be provided. Such molecules include any of the “hedgehog” proteins, or the DNA's encoding them.

Coatings used with an exemplary embodiment of the present invention may comprise a polymeric material/drug agent matrix formed, for example, by admixing a drug agent with a liquid polymer, in the absence of a solvent, to form a liquid polymer/drug agent mixture. Curing of the mixture typically may occur in-situ. To facilitate curing, a cross-linking or curing agent may be added to the mixture prior to application thereof. Addition of the cross-linking or curing agent to the polymer/drug agent liquid mixture should not occur too far in advance of the application of the mixture in order to avoid over-curing of the mixture prior to application thereof. Over curing may be avoided in the method and device according to an exemplary embodiment of the present invention by virtue of the fact that the solution of drug and polymer may be frozen, which may thereby avoid the problem of overcuring.

Curing may also occur in-situ by exposing the polymer/drug agent mixture, after application to the luminal surface, to radiation such as ultraviolet radiation or laser light, heat, or by contact with metabolic fluids such as water at the site where the mixture has been applied to the luminal surface. In coating systems employed in conjunction with the present invention, the polymeric material may be either bioabsorbable or biostable. Any of the polymers described herein that may be formulated as a liquid may be used to form the polymer/drug agent mixture.

In an exemplary embodiment, the polymer used to coat the medical device may be provided in the form of a coating on an expandable portion of a medical device. After applying the drug solution to the polymer and evaporating the volatile solvent from the polymer, the medical device may be inserted into a body lumen where it may be positioned in a target location. In the case of a balloon catheter, the expandable portion of the catheter may subsequently be expanded to bring the drug-impregnated polymer coating into contact with the lumen wall. The drug may be released from the polymer as it slowly dissolves into the aqueous bodily fluids and diffuses out of the polymer. This may enable administration of the drug to be site-specific, limiting the exposure of the rest of the body to the drug.

Very thin polymer coatings may be possible according to an exemplary embodiment of the present invention. It is also within the scope of the present invention to apply multiple layers of polymer coating onto a medical device. Such multiple layers may be of the same or different polymer materials.

The polymer of the present invention may be hydrophilic or hydrophobic, and may be selected from the group consisting of polycarboxylic acids, cellulosic polymers, including cellulose acetate and cellulose nitrate, gelatin, polyvinylpyrrolidone, cross-linked polyvinylpyrrolidone, polyanhydrides including maleic anhydride polymers, polyamides, polyvinyl alcohols, copolymers of vinyl monomers such as EVA, polyvinyl ethers, polyvinyl aromatics, polyethylene oxides, glycosaminoglycans, polysaccharides, polyesters including polyethylene terephthalate, polyacrylamides, polyethers, polyether sulfone, polycarbonate, polyalkylenes including polypropylene, polyethylene and high molecular weight polyethylene, halogenated polyalkylenes including polytetrafluoroethylene, polyurethanes, polyorthoesters, proteins, polypeptides, silicones, siloxane polymers, polylactic acid, polyglycolic acid, polycaprolactone, polyhydroxybutyrate valerate and blends and copolymers thereof as well as other biodegradable, bioabsorbable and biostable polymers and copolymers. Coatings from polymer dispersions such as polyurethane dispersions (BAYHDROL®, etc.) and acrylic latex dispersions are also within the scope of the present invention. The polymer may be a protein polymer, fibrin, collagen and derivatives thereof, polysaccharides such as celluloses, starches, dextrans, alginates and derivatives of these polysaccharides, an extracellular matrix component, hyaluronic acid, or another biologic agent or a suitable mixture of any of these, for example. In one embodiment of the invention, the preferred polymer is polyacrylic acid, available as HYDROPLUS® (Boston Scientific Corporation, Natick, Mass.), and described in U.S. Pat. No. 5,091,205, the disclosure of which is hereby incorporated herein by reference. U.S. Pat. No. 5,091,205 describes medical devices coated with one or more polyisocyanates such that the devices become instantly lubricious when exposed to body fluids. In another preferred embodiment of the invention, the polymer is a copolymer of polylactic acid and polycaprolactone.

While the present invention has been described in connection with the foregoing representative embodiment, it should be readily apparent to those of ordinary skill in the art that the representative embodiment is exemplary in nature and is not to be construed as limiting the scope of protection for the invention as set forth in the appended claims.

1. A method for coating at least a portion of at least one medical device, comprising:
directing a laser at a target, the target including a drug and a polymer;
vaporizing by the laser at least a portion of the target into a vapor cone; and
arranging the at least one medical device in the vapor cone.

2. The method of claim 1, further comprising dissolving the drug and the polymer in a solvent to prepare a target solution, the target solution forming the target.

3. The method of claim 2, further comprising filtering the target solution.

4. The method of claim 2, further comprising:
freezing the target solution to make the target; and
mounting the target on a refrigerated rotating assembly.

5. The method of claim 2, further comprising:
arranging in a container the target solution in a liquid state to make the target; and
mixing the target solution to maintain a uniform solution of the drug and the polymer in the solvent.

6. The method of claim 5, wherein the mixing of the target solution is performed by a stirrer in the container.

7. The method of claim 5, wherein the mixing of the target solution is performed by a sonicator in the container.

8. The method of claim 2, further comprising:
enclosing the target and the at least one medical device in an evaporation chamber; and
removing by a pump the solvent from the evaporation chamber after the vaporizing operation.

9. The method of claim 1, further comprising, after the vaporizing operation, directing a gas flow to transport the drug and the polymer to the at least one medical device.

10. The method of claim 9, wherein the gas flow includes an inert gas.

11. The method of claim 1, wherein the at least one medical device includes at least one stent.

12. The method of claim 1, wherein the laser includes a UV laser.

13. The method of claim 1, wherein the laser is pulsed.

14. The method of claim 1, further comprising directing at least one of the laser and a second laser at a second target, the second target including at least one of a second drug and a second polymer, the at least one of the laser and the second laser vaporizing the second target into the vapor cone.

15. A medical device having a coating applied by a method, the method comprising:
directing a laser at a target, the target including a drug and a polymer;
vaporizing by the laser at least a portion of the target into a vapor cone; and
arranging the medical device in the vapor cone.

16. The medical device of claim 15, wherein the method further comprises dissolving the drug and the polymer in a solvent to prepare a target solution, the target solution forming the target.

17. The medical device of claim 15, wherein the method further comprises: arranging in a container the target solution in a liquid state to make the target; and
mixing the target solution to maintain a uniform solution of the drug and the polymer in the solvent.

18. The medical device of claim 17, wherein the mixing of the target solution is performed by a stirrer in the container.

19. The medical device of claim 17, wherein the mixing of the target solution is performed by a sonicator in the container.

20. The medical device of claim 15, wherein the method further comprises:
enclosing the target and the at least one medical device in an evaporation chamber; and
removing by a pump the solvent from the evaporation chamber after the vaporizing operation.

21. The medical device of claim 15, wherein the medical device includes at least one stent.

22. The medical device of claim 15, wherein the coating includes a masking material.

23. The medical device of claim 15, wherein the coating is chosen from a group consisting of a polymer with a suspended drug, a non-thrombogenic agent, a lubricious material, a non-slippery material, a radioactive agent, and a magnetic signature.

24. The medical device of claim 15, wherein the coating is a radiopaque agent.
